(19) United States
(12) Patent Application Publication
(10) Pub. No.: US 2019/0014660 A1
(43) Pub. Date: Jan. 10, 2019

(54) CIRCUIT OF AN ELECTRONIC CONTROL UNIT

(71) Applicant: WABCO Europe BVBA, Brussels (BE)

(72) Inventors: Christian BRAMMER, Bergen (DE); Tobias WUSTRACK, Hannover (DE)

(21) Appl. No.: 16/082,457

(22) PCT Filed: Feb. 2, 2017
(86) PCT No.: PCT/EP2017/000134

§ 371 Date: Sep. 5, 2018

(30) Foreign Application Priority Data
Mar. 5, 2016 (DE) 10 2016 002 821.1

(51) Int. Cl. H05K 1/02; H01R 12/65; H01R 12/58; H05K 1/11

(52) U.S. Cl. CPC H05K 1/0281; H01R 12/65; H05K 2201/2009; H05K 1/11; H05K 2201/1059; H01R 12/585

(57) ABSTRACT

A circuit of an electronic control unit is disclosed, with a plurality of conductor tracks manufactured in punched-grid constructional form or in flexible-film constructional form, of which at least one conductor track comprises a contact region with at least one conductor-track contact bore for pressing in a contact pin of a connector element or of an electronic component. The contact region of the conductor track is reinforced with an additional supporting washer comprising an electrically conducting metal sheet, and the supporting washer covers the contact region of the conductor track. The supporting washer is further provided with a supporting-washer contact bore arranged coaxially with respect to the conductor-track contact bore, and the supporting washer is arranged on one side of the conductor track and also connected to the conductor track.

### CROSS-REFERENCE TO RELATED APPLICATIONS

This application is a national phase entry of PCT/EP2017/000134, filed Feb. 2, 2017, which claims priority to German Patent Application No. 10 2016 002 821.1, filed Mar. 5, 2016, both of which are incorporated herein by reference in their entirety.

### FIELD OF THE INVENTION

The invention relates to a circuit of an electronic control unit, with a plurality of conductor tracks manufactured in punched-grid constructional form or in flexible-film constructional form, of which at least one conductor track includes a contact region with at least one conductor-track contact bore for pressing in a contact pin of a connector element or of an electronic component.

### BACKGROUND OF THE INVENTION

In electronic control units—such as, for example, control devices of motor vehicles—via which relatively large electrical currents are distributed, the conductor tracks have to have appropriately large line cross-sections. In addition, the control units are to take up as little construction space as possible and utilize the available construction space optimally, which can be attained by a vaulted or kinked constructional form. The conductor tracks of the circuits of electronic control units are therefore frequently manufactured in punched-grid constructional form or in flexible-film constructional form, since these enable—by bending, vaulting and kinking—a flexible styling deviating from a flat sheet-metal blank.

In a circuit realized in punched-grid constructional form, the conductor tracks are punched out from a sheet-metal strip consisting of electrically conducting metal—such as, for example, from a copper sheet—in which case the conductor tracks are firstly connected to one another via connecting webs. Subsequently the conductor tracks are, for example, extrusion-coated intermittently with an electrically non-conducting synthetic material and hence mechanically connected to one another. After the curing of the synthetic material, the connecting webs are punched out, so that the conductor tracks have then been electrically separated from one another and can be brought into a suitable shape by bending and also kinking.

In a circuit realized in flexible-film constructional form, the conductor tracks are, for example, integrally punched out from a sheet-metal strip consisting of electrically conducting metal, and subsequently connected to one another on both sides by adhesive bonding with an electrically non-conducting flexible film of synthetic material. The conductor tracks have consequently been electrically separated from one another and can be brought into a suitable shape by bending and kinking.

For the rational equipping of the circuits with connector elements—such as, for example, connector sockets for plugging cable connectors in or on—and with electronic components—such as transistors, resistors, capacitors and so on—use is increasingly being made of solder-free plug-in connections, via which the components in question are both mechanically attached to the conductor track in question and also electrically connected to the latter. For this purpose, the conductor tracks each exhibit at least one contact region with at least one conductor-track contact bore for pressing in a contact pin of a connector element or of an electronic component.

In DE 10 2004 006 575 A1 a power distributor realized in punched-grid constructional form is described, in which connector elements with two or three contact pins have been pressed into assigned conductor-track contact bores.

From DE 20 2009 009 933 U1 a circuit, realized in punched-grid constructional form, of an electronic control unit is known, in which the connector elements that have been provided are realized, at least in the base region, bent into a U-shape and exhibit, on each base shank, two contact pins for pressing into two respective conductor-track contact bores of adjacent conductor tracks.

In DE 10 2010 039 204 A1 a circuit, realized in flexible-film constructional form, of an electronic control unit is described, in which the conductor tracks have been reinforced at the contact bores thereof. In a first embodiment, a socket or a hollow rivet has been inserted into an appropriately enlarged conductor-track contact bore. In a second embodiment, a conductor track has been extrusion-coated with an electrically conducting synthetic material at the appropriately enlarged conductor-track contact bore in an annular contour. The reinforcement of the conductor tracks in the immediate region of the conductor-track contact bore serves for enlarging the electrical area of contact with the contact pins. A mechanical reinforcement of the contact regions of the conductor tracks is, however, barely obtained thereby.

A known problem in connection with the equipping of circuits realized in punched-grid constructional form and in flexible-film constructional form occurs when the contact pins of connector elements and electronic components are pressed into the assigned contact bores and the contact regions are unintentionally deformed. By means of this, an unfavorable location and an inadequate mechanical attachment of the components in question may result. Similarly, the electrical contact between the conductor-track contact bores and the contact pins of the components may have been impaired thereby. The problem arises especially when the conductor tracks have been punched out of a sheet having a comparatively small thickness of, for instance, less than 1 mm.

### SUMMARY OF THE INVENTION

The present invention provides a circuit of an electronic control unit of the aforementioned type, in which the conductor tracks have a relatively small sheet thickness, with a reinforcement, which is easy and inexpensive to manufacture and to install, of the conductor tracks at the contact regions, by which a deformation of the conductor tracks is securely prevented also when the contact pins are pressed robustly into the conductor-track contact bores.

By a “relatively small sheet thickness”, a sheet thickness is understood that is so small that the sheet is comparatively easy to bend and/or can withstand flexural loads without damage by reason of the flexibility thereof in operation. A relatively small sheet thickness in this sense may amount to less than or equal to 0.8 mm and may also be designated as foil.

In one embodiment, a circuit of an electronic control unit comprises a plurality of conductor tracks manufactured in punched-grid constructional form or in flexible-film constructional form, of which at least one conductor track comprises a contact region with a conductor-track contact bore for pressing in a contact pin of a connector element or of an electronic component, and a supporting washer reinforcing and covering the contact region of the at least one conductor track, the supporting washer comprising an electrically conducting metal sheet, and a supporting-washer contact bore arranged coaxially with respect to the conductor-track contact bore, wherein the supporting washer is arranged on one side of the at least one conductor track and also connected to the at least one conductor track.

In certain embodiments, such as in the case of a relatively small sheet thickness of the conductor tracks of, for example, 0.8 mm or less, the supporting washer can prevent a deformation of the conductor tracks when the contact pins are pressed into the conductor-track contact bores.

Consequently the contact region of the conductor track has been reinforced, as a result of which a deformation of the conductor track in the region of the conductor-track contact bore when the contact pin is pressed in has been prevented in simple and inexpensive manner. In certain embodiments, the contact area for the contact pin has also been enlarged by the supporting washer, and hence the electrical contact between the conductor track and the connector element or the electronic component has been improved. The supporting washer can be cut out or punched out from an appropriately thick sheet and can be arranged, in identical realization, on several contact regions of the circuit.

In these or other embodiments, the supporting washer is arranged on the side of the conductor track from which the contact pin of the connector element or of the electronic component is inserted into the conductor-track contact bore. Accordingly, when the contact pin is pressed into the conductor-track contact bore the supporting washer is pressed against the conductor track, so that the connection between the supporting washer and the conductor track can be realized less robustly.

In these or other embodiments, in order to exhibit great stability and to reinforce the contact region of the conductor track sufficiently, the supporting washer can have at least three times the thickness of the conductor track. In such an embodiment, the supporting washer is also sufficiently stiff for a robust pressing-in of the contact pins.

In these or other embodiments, the supporting washer can be connected to the conductor track by means of a clinch-rivet joint (Tox clinch joint). In contrast to a riveted joint or screwed joint, a clinch-rivet joint requires no bore. In comparison with a welded joint or soldered joint, a clinch-rivet joint manages without thermal action on the components to be connected, and without supplementary materials.

As an alternative, the supporting washer may also be connected to the conductor track by an extrusion coating with a synthetic material. The synthetic material that is used may optionally be electrically conducting or non-conducting.

In this embodiment, the extrusion coating of the conductor track and of the supporting washer with synthetic material can have a frame-like design and encompasses the outer edges of the conductor track and of the supporting washer in bracket-like manner. This provides a stable positive connection between the supporting washer and the conductor track. In comparison with a rivet-like extrusion coating of several bores, which is likewise possible, in the case of the frame-like extrusion coating no fastening bore is required.

In these or other embodiments, in order to avoid a bulging of the conductor track in the region of the conductor-track contact bore when the contact pin is pressed in, the diameter of the conductor-track contact bore can be enlarged so far that an electrical connection of the conductor track to the contact pin of the connector element or of the electronic component exists only via the supporting-washer contact bore. By reason of the relatively large thickness of the supporting washer, the area of contact of the supporting washer with the contact pin of the connector element or of the electronic component is fully sufficient.

According to a further embodiment for connecting the supporting washer to the conductor track, the supporting washer can be connected to the conductor track by a sheath consisting of an electrically conducting metal or by a hollow rivet which has been inserted into the appropriately widened contact bores of the conductor track and of the supporting washer and also attached at the end. This attachment may, for instance, have been realized by a beading. By virtue of the sheath or the hollow rivet, on the one hand the mechanical connection between the supporting washer and the conductor track is established, and on the other hand with the cylindrical internal surface of said sheath or of said rivet a relatively large electrical contact area with respect to the contact pin of the connector element or of the electronic component is formed.

### BRIEF DESCRIPTION OF THE DRAWING

The invention is described in greater detail below with reference to the accompanying figures, in which:

FIG. 1 shows a first embodiment of a contact region, designed in accordance with the invention, of a conductor track in a perspective view,

FIG. 1a shows the contact region of the conductor track according to FIG. 1 in a sectional view

FIG. 2 shows a circuit of an electronic control unit with several conductor tracks and contact regions in a perspective view,

FIG. 3 shows a second embodiment of a contact region, designed in accordance with the invention, of a conductor track in a perspective view,

FIG. 3a shows the contact region of the conductor track according to FIG. 3 in a sectional view,

FIG. 4 shows a third embodiment of a contact region, designed in accordance with the invention, of a conductor track in a perspective view, and

FIG. 4a shows the contact region of the conductor track according to FIG. 4 in a sectional view.

### DETAILED DESCRIPTION

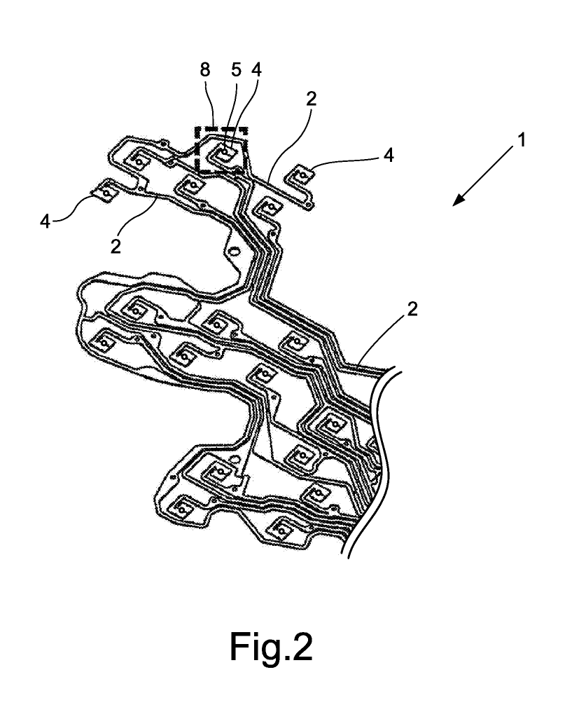

With reference to the specific embodiment of the figures, wherein like numerals generally indicate like parts throughout the several views, FIG. 2 shows a circuit 1, manufactured in punched-grid constructional form, of an electronic control unit is illustrated which comprises several conductor tracks 2 which are electrically separated from one another. The conductor tracks 2 each exhibit at least one contact region 4 with at least one conductor-track contact bore 5 for pressing in a contact pin 6 of a connector element 7 or of an electronic component. In the following, embodiments of the invention will be elucidated in three realizations on the basis of the contact region 4, marked in FIG. 2 by a dashed frame 8, of a conductor track 2.

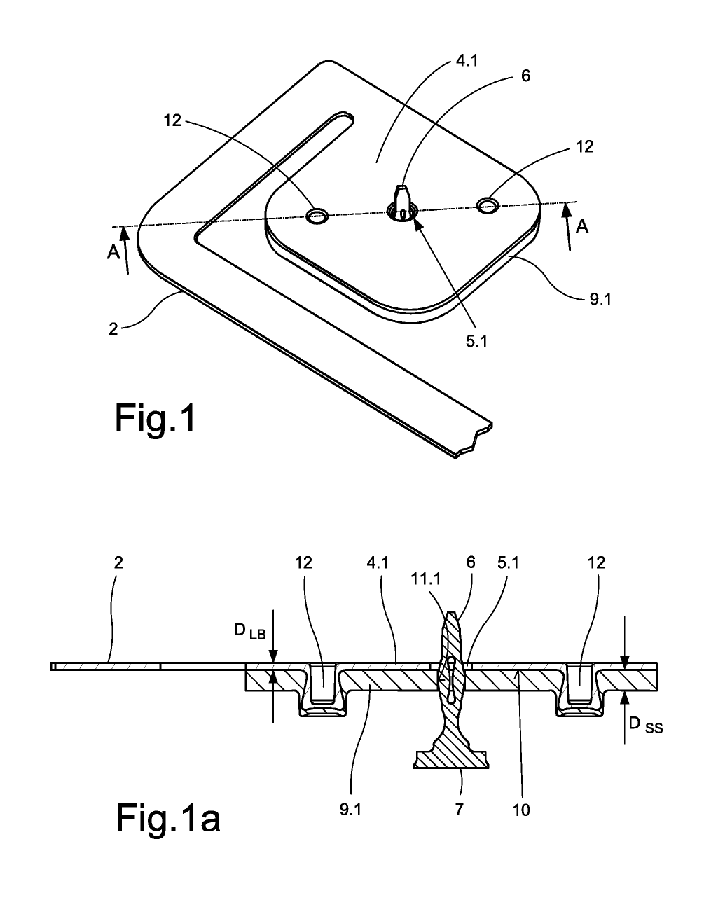

A first embodiment of a contact region 4.1, according to the invention, of the conductor track 2 is represented in FIG. 1 in a perspective view and in FIG. 1a in a sectional view along section line A-A according to FIG. 1. The conductor track 2 has been cut out or punched out from a sheet-metal strip, the thickness DLB of which in this embodiment example amounts to at most 0.8 mm (DLB≤0.8 mm). In order to prevent a deformation of the conductor track 2 when the contact pin 6 is inserted into the conductor-track contact bore 5.1, or in order also to enable a robust and nevertheless damage-free pressing of the contact pin 6 into the conductor-track contact bore 5.1, the contact region 4.1 of the conductor track 2 has been reinforced with an additional supporting washer 9.1. The supporting washer 9.1 comprises, and may optionally consist of, an electrically conducting metal sheet of comparatively large thickness Dₛₛ, such as, for example, of a copper sheet, and covers the entire contact region 4.1 of the conductor track 2. The supporting washer 9.1 in this example is arranged on the underside 10 of the conductor track 2, from which the contact pin 6 of the connector element 7 or of the electronic component is inserted into the conductor-track contact bore 5.1. In addition, the supporting washer 9.1 exhibits a continuous supporting-washer contact bore 11.1 arranged coaxially with respect to the conductor-track contact bore 5.1. In the present case, the supporting washer 9.1 has been connected to the conductor track 2 by means of a clinch-rivet joint 12 realized at two places. The diameter of the conductor-track contact bore 5.1 is so large that an electrical connection of the conductor track 2 to the contact pin 6 of the connector element 7 or of the electronic component exists only via the supporting-washer contact bore 11.1. By this means, a bulging of the conductor track 2 in the region of the conductor-track contact bore 5.1 when the contact pin 6 is inserted is advantageously prevented.

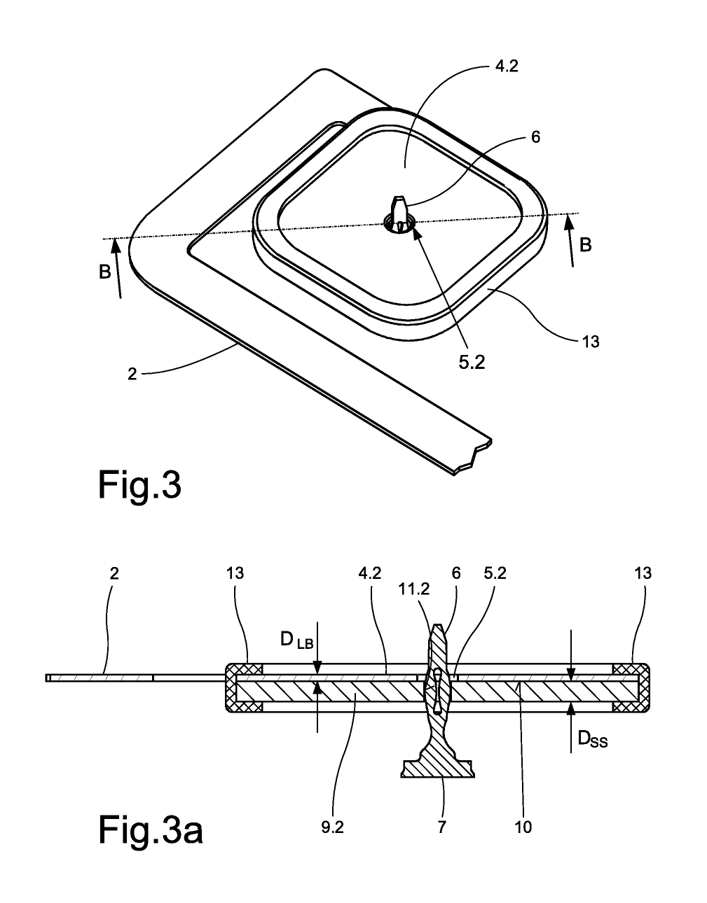

A second embodiment of a contact region 4.2, according to the invention, of the conductor track 2 is represented in FIG. 3 in a perspective view and in FIG. 3a in a sectional view along section line B-B according to FIG. 3. The supporting washer 9.2 in this realization of the contact region 4.2 is likewise arranged on the underside 10 of the conductor track 2 from which the contact pin 6 of the connector element 7 or of the electronic component is inserted into the conductor-track contact bore 5.2, and is provided with a supporting-washer contact bore 11.2 which is arranged in positionally correct manner—that is to say, coaxially with respect to the conductor-track contact bore 5.2. Now, however, the supporting washer 9.2 has been connected to the conductor track 2 by means of an extrusion coating 13 consisting of a synthetic material. The synthetic-material extrusion coating 13 of the conductor track 2 and of the supporting washer 9.2 is of frame-like design and encompasses the outer edges of the conductor track 2 and also of the supporting washer 9.2 in frame-like manner. The synthetic material that is used may optionally be of electrically conducting or non-conducting design. Also in this realization of the contact region 4.2, the diameter of the conductor-track contact bore 5.2 has been enlarged so far that an electrical connection of the conductor track 2 to the contact pin 6 of the connector element 7 or of the electronic component exists exclusively via the supporting-washer contact bore 11.2.

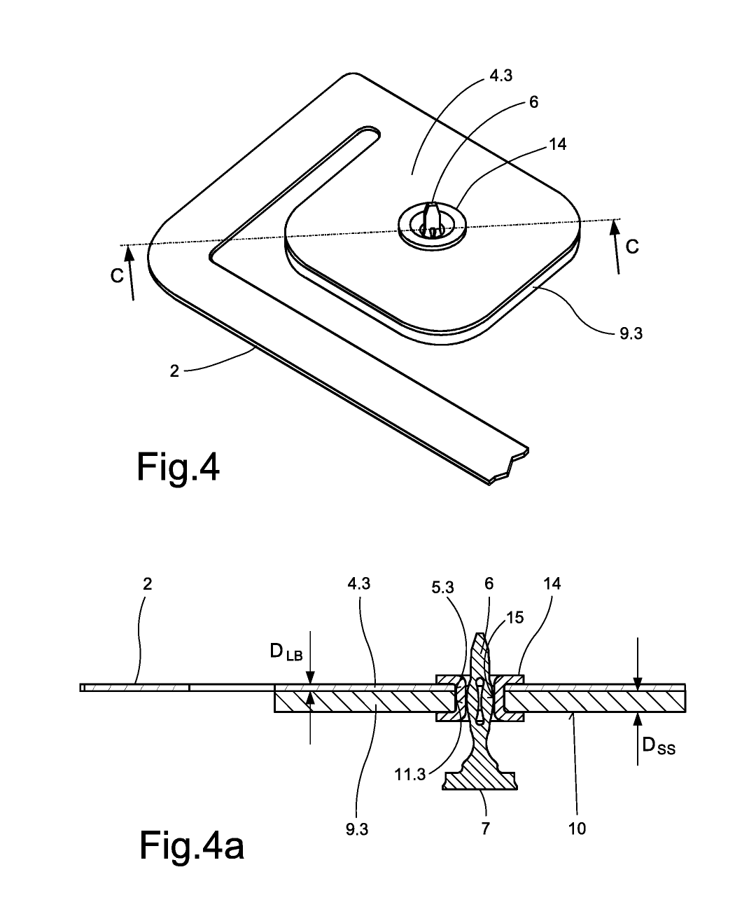

A third embodiment of a contact region 4.3, according to the invention, of the conductor track 2 is represented in FIG. 4 in a perspective view and in FIG. 4a in a sectional view along section line C-C according to FIG. 4. The supporting washer 9.3 also in this realization of the contact region 4.3 is arranged on the underside 10 of the conductor track 2, from which the contact pin 6 of the connector element 7 or of the electronic component is inserted into the conductor-track contact bore 5.3, and is provided with a supporting-washer contact bore 11.3 arranged in positionally correct manner. Now, however, the supporting washer 9.3 has been connected to the conductor track 2 by means of a sheath 14 consisting of an electrically conducting metal or by means of a hollow rivet which has been inserted into the appropriately widened contact bores 5.3, 11.3 of the conductor track 2 or of the supporting washer 9.3 and has also been axially beaded at the end. The electrical connection of the conductor track 2 to the contact pin 6 of the connector element 7 or of the electronic component exists in this case via the relatively large cylindrical internal surface 15 of the sheath 14 or of the hollow rivet.

The terms “comprising” or “comprise” are used herein in their broadest sense to mean and encompass the notions of “including,” “include,” “consist(ing) essentially of,” and “consist(ing) of. The use of “for example,” “e.g.,” “such as,” and “including” to list illustrative examples does not limit to only the listed examples. Thus, “for example” or “such as” means “for example, but not limited to” or “such as, but not limited to” and encompasses other similar or equivalent examples. The term “about” as used herein serves to reasonably encompass or describe minor variations in numerical values measured by instrumental analysis or as a result of sample handling. Such minor variations may be in the order of ±0-25, ±0-10, ±0-5, or ±0-2.5, % of the numerical values. Further, The term “about” applies to both numerical values when associated with a range of values. Moreover, the term “about” may apply to numerical values even when not explicitly stated.

Generally, as used herein a hyphen “-” or dash “—” in a range of values is “to” or “through”; a “>” is “above” or “greater-than”; a “≥” is “at least” or “greater-than or equal to”; a “<” is “below” or “less-than”; and a “≤” is “at most” or “less-than or equal to.” On an individual basis, each of the aforementioned applications for patent, patents, and/or patent application publications, is expressly incorporated herein by reference in its entirety in one or more non-limiting embodiments.

It is to be understood that the appended claims are not limited to express and particular compounds, compositions, or methods described in the detailed description, which may vary between particular embodiments which fall within the scope of the appended claims.

With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

The present invention has been described herein in an illustrative manner, and it is to be understood that the terminology which has been used is intended to be in the nature of words of description rather than of limitation. Many modifications and variations of the present invention are possible in light of the above teachings. The present invention may be practiced otherwise than as specifically described within the scope of the appended claims. The subject matter of all combinations of independent and dependent claims, both single and multiple dependent, is herein expressly contemplated.

What is claimed is:

1. A circuit of an electronic control unit comprising:
a plurality of conductor tracks manufactured in punched-grid constructional form or in flexible-film constructional form, of which at least one conductor track comprises a contact region with a conductor-track contact bore for pressing in a contact pin of one of a connector element or an electronic component; and
a supporting washer reinforcing and covering the contact region of the at least one conductor track, the supporting washer comprising:
an electrically conducting metal sheet; and
a supporting-washer contact bore arranged coaxially with respect to the conductor-track contact bore;
wherein the supporting washer is arranged on one side of the at least one conductor track and also connected to the at least one conductor track.

2. The circuit as claimed in claim 1, wherein the supporting washer is arranged on a side of the at least one conductor track from which the contact pin is inserted into the conductor-track contact bore.

3. The circuit as claimed in claim 1, wherein the supporting washer has a thickness at least three times a thickness of the conductor track.

4. The circuit as claimed in claim 1, wherein the supporting washer is connected to the conductor track by a clinch-rivet joint.

5. The circuit as claimed in claim 1, wherein the supporting washer is connected to the conductor track by an extrusion coating with a synthetic material.

6. The circuit as claimed in claim 5, wherein the synthetic-material extrusion coating encompasses the outer edges of the conductor track and of the supporting washer.

7. The circuit as claimed in claim 4, wherein the diameter of the conductor-track contact bore is larger than that of the contact pin and an electrical connection of the conductor track to the contact pin exists only via the supporting-washer contact bore.

8. The circuit as claimed in claim 1, wherein the supporting washer is connected to the conductor track by a sheath comprising an electrically conducting metal and inserted into the conductor-track contact bore and the supporting-washer contact bore.

9. The circuit as claimed in claim 1, wherein the supporting washer is connected to the conductor track by a hollow rivet inserted into the conductor-track contact bore and the supporting-washer contact bore.
